(19) United States
(12) Patent Application Publication
(10) Pub. No.: US 2018/0026122 A1
(43) Pub. Date: Jan. 25, 2018

(54) B-TRAN Geometry and Structure That Provides Both High Gain and High Current Density

(71) Applicants: Richard A. Blanchard, Los Altos, CA (US); William C. Alexander, Spicewood, TX (US)

(72) Inventors: Richard A. Blanchard, Los Altos, CA (US); William C. Alexander, Spicewood, TX (US)

(73) Assignee: Ideal Power Inc., Austin, TX (US)

(21) Appl. No.: 15/530,663

(22) Filed: Oct. 9, 2015

(51) Int. Cl. H01L 29/747; H01L 29/66; H01L 29/40; H01L 29/06; H01L 29/16

(52) U.S. Cl. CPC H01L 29/747; H01L 29/0623; H01L 29/0696; H01L 29/16; H01L 29/404; H01L 29/407; H01L 29/408; H01L 29/401; H01L 29/66386

(57) ABSTRACT

Three optimizations are provided for B-TRAN devices which include field plate trenches: 1) the trench dielectric thickness is large enough to withstand the base-to-emitter voltage, but thin enough to provide good electrical coupling between the poly field plate and the adjacent p-type silicon; 2) the base contact width is small enough to provide an acceptably low reverse base contact region pinch-off voltage, but large enough to avoid degradation of both base resistance; and 3) the emitter width is small enough to keep an acceptably high current density at the emitter's center.

### BACKGROUND

The bi-directional bipolar transistor or “B-TRAN” is a three-layer, four terminal semiconductor device, as shown in FIG. 2. It is a symmetrical device, meaning that the polarity of the voltage placed on the two “end” terminals 102 and 104 determines which of these two terminals functions as the emitter 104 (i.e., has a forward biased junction), and which of these two terminals functions as the collector 102 (i.e., has a reverse biased junction).

When biased to conduct, a B-TRAN with an operating voltage of 600 to 1200 volts has a current gain in the range of e.g. 5-20, and when biased “off,” is capable of withstanding this same voltage in either direction.

In addition, as a bipolar transistor, it has an on-voltage (Vice-SAT) that can be as low as 0.2 volts at high currents, which is a lower voltage than many other types of devices. Since the B-TRAN is symmetrical, it can be used in circuits requiring a bi-directional switch.

A device symbol that shows the symmetry of a B-TRAN is shown in FIG. 4. This device has two separate base contact regions, one on each surface as shown in FIGS. 2 and 3.

The B-TRAN structure shown in FIG. 3 was discussed in an earlier invention disclosure titled “A Bi-Directional Bipolar Transistor (“B-TRAN”) with a Field Plate in a Trench” (now published as WO 2016061140).

### SUMMARY

The present application teaches three optimizations in a B-TRAN having field plates:
By making the dielectric thickness in the field plate trenches large enough to withstand the base-to-emitter voltage, but thin enough to provide good electrical coupling between the poly field plate and the adjacent p-type silicon, the voltage at which the base contact region becomes isolated from the remainder of the base region by the depletion of the reverse biased pn-junction is made acceptably low.
By choosing the trench-to-trench spacing that determines the base contact width to provide an acceptably low reverse base contact region pinch-off voltage, the trench-to-trench spacing for the base contact region is balanced to avoid degradation of both base resistance and pinch-off voltage.
By choosing an emitter width with an acceptably high current density at its center, the efficiency of the emitter is kept acceptably high.

### BRIEF DESCRIPTION OF THE DRAWINGS

The disclosed inventions will be described with reference to the accompanying drawings, wherein:

FIG. 1 schematically shows a cross-section of device structures on one surface of a B-TRAN-type device, showing structures used in the active region and also in the transition to the edge termination.

FIG. 2 schematically shows a bidirectional bipolar transistor, or “B-TRAN,” having dielectric-filled trenches.

FIG. 3 schematically shows one sample embodiment of a B-TRAN having field plates in trenches.

FIG. 4 shows the preferred circuit symbol for a B-TRAN-type device.

### DETAILED DESCRIPTION OF SAMPLE EMBODIMENTS

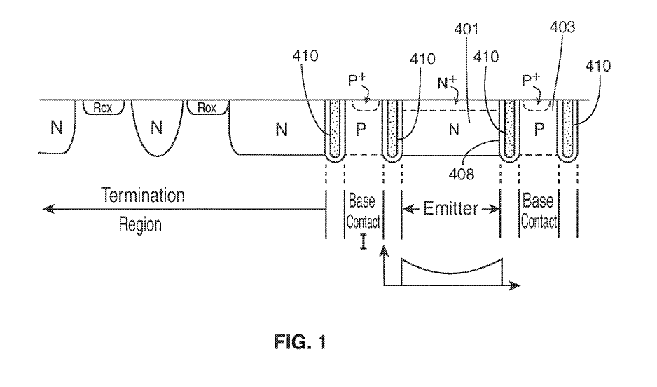

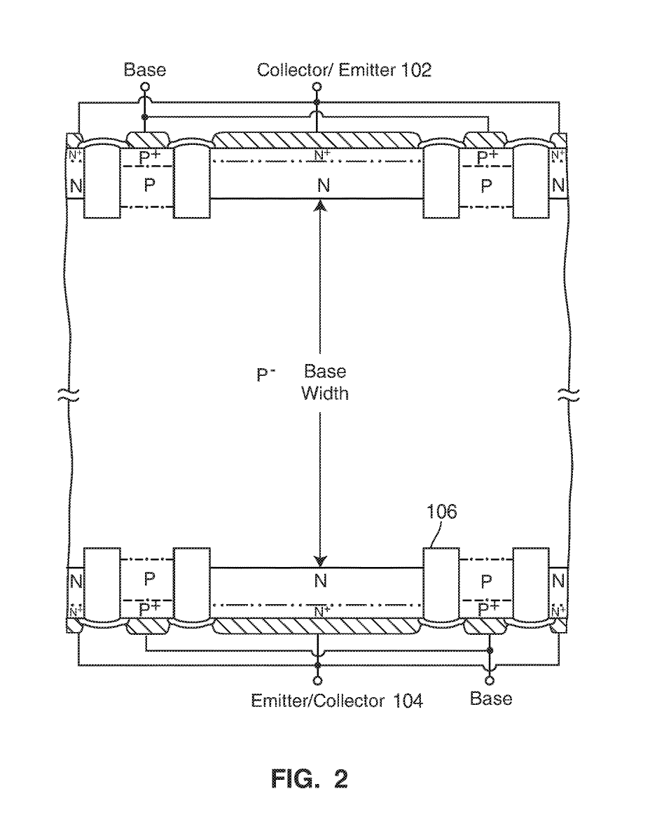

The goal of the present disclosure is to document further inventive features that can be included in the structure of a B-TRAN, and which result in improved device performance. The three inventive aspects of the present disclosure are shown in FIG. 1, and are described more fully below.

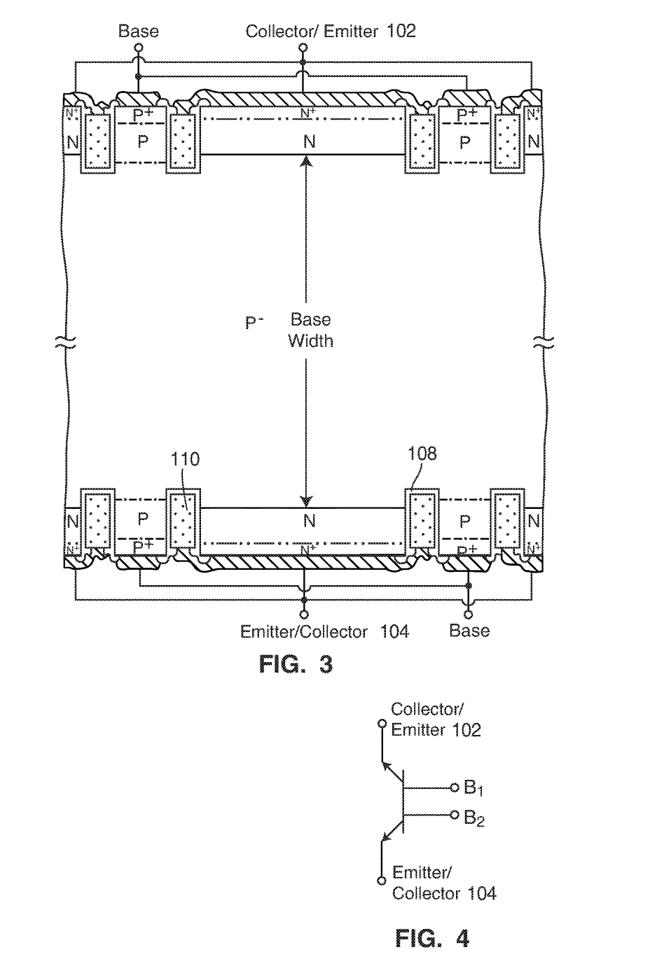

The poly field plate 410 in FIG. 1 is electrically connected to the adjacent emitter 401 just as in FIG. 3. The thickness of the dielectric layer 108 in the trench between the poly field plate 110 and the adjacent p-type silicon may be adjusted to provide an acceptably low reverse base contact region pinch-off voltage. A smaller dielectric layer thickness allows for better coupling between the poly field plate in the trench and the p-type silicon that is adjacent to the trench. However, if this dielectric thickness is too small, it is unable to withstand the voltage difference between the poly field plate, which is at the same voltage as the emitter regions, and the base region. This layer will suffer permanent damage, electrically connecting the base and emitter regions on the one surface of the B-TRAN. By selecting a dielectric thickness that is large enough to withstand the base-to-emitter voltage, but thin enough to provide good electrical coupling between the poly field plate and the adjacent p-type silicon, the voltage at which the base contact region becomes isolated from the remainder of the base region by the depletion of the reverse biased pn-junction may be made acceptably low. Computer simulations have shown a decrease in base contact region pinch-off voltage as the dielectric thickness is reduced.

The trench-to-trench spacing that determines the base contact region 403's width is also chosen to provide an acceptably low reverse base contact region pinch-off voltage. This spacing, as shown in FIG. 1, must be sufficiently large that an electrical connection may be made to it that allows the peak base current to flow with a low resistance. However, as discussed above, if the width of the base contact region is too large, the base contact region pinch-off voltage may be unacceptably high. The selection of the trench-to-trench spacing for the base contact region is a balance between its resistance and the base contact region pinch-off voltage.

The trench-to-trench spacing that determines the emitter 401's width is chosen to provide an acceptably high current density as discussed below. It is well known that in a bipolar transistor, the portion of the emitter region that is closest to a base region has the highest current density. A typical current density vs. distance from the lateral edge of the emitter is shown in FIG. 1 for the region below the n-type emitter region. As the emitter width is increased, the current density continues to decrease, with the center of the emitter region contributing an ever-smaller percentage of the current. This behavior is well known as “emitter current crowding.” By choosing an emitter width with an acceptably high current density at its center, the efficiency of the emitter 401 may be kept acceptably high.

The three aspects of B-TRAN design discussed above may be included in a single B-TRAN structure, allowing a device to be fabricated that has acceptable performance with respect to base contact region pinch-off voltage, emitter-to-base breakdown voltage, base contact region resistance, and device current density.

Additional general background, which helps to show variations and implementations, can be found in the following patents and publications, all of which are hereby incorporated by reference: U.S. Pat. No. 7,599,196, U.S. Pat. No. 7,778,045, U.S. Pat. No. 8,295,069, U.S. Pat. No. 8,300,426, U.S. Pat. No. 8,345,452, U.S. Pat. No. 8,391,033, U.S. Pat. No. 8,395,910, U.S. Pat. No. 8,400,800, U.S. Pat. No. 8,406,265, U.S. Pat. No. 8,432,711, U.S. Pat. No. 8,441,819, U.S. Pat. No. 8,446,042, U.S. Pat. No. 8,446,043, U.S. Pat. No. 8,446,745, U.S. Pat. No. 8,451,637, U.S. Pat. No. 8,461,718, U.S. Pat. No. 8,471,408, U.S. Pat. No. 8,514,601, U.S. Pat. No. 8,531,858, U.S. Pat. No. 9,007,796, U.S. Pat. No. 9,029,909, U.S. Pat. No. 9,035,350, U.S. Pat. No. 9,042,131, U.S. Pat. No. 9,054,706, U.S. Pat. No. 9,054,707, U.S. Pat. No. 9,059,710, U.S. Pat. No. 9,077,185, U.S. Pat. No. 9,118,247, U.S. Pat. No. 9,124,095, U.S. Pat. No. 9,130,461; WO 2008/008143, WO 2011/008567, WO 2011/022442, WO 2012/075172, WO 2012/075189.

Additional general background, which helps to show variations and implementations, as well as some features which can be implemented synergistically with the inventions claimed below, may be found in the following US patent applications. All of these applications have at least some common ownership, copendency, and inventorship with the present application, and all of them, as well as any material directly or indirectly incorporated within them, are hereby incorporated by reference: US 2012-0051100 A1, US 2012-0279567 A1, US 2013-0307336 A1, US 2013-0314096 A1, US 2014-0009979 A1, US 2014-0319911 A1, US 2015-0061569 A1, US 2015-0214055 A1, US 2015-0214299 A1, US 2015-0214782 A1, US 2015-0214784 A1, US 2015-0222146 A1, US 2015-0222147 A1, US 2015-0222194 A1, US 2015-0270771 A1, US2015-0270837 A1, US2015-0280613 A1, PCT/US14/16740, PCT/US14/26822, PCT/US14/35954, PCT/US14/35960, PCT/US14/43962, PCT/US14/69611, PCT/US15/11827, PCT/US15/37042, Ser. Nos. 14/182,243, 14/182,245, 14/182,246, 14/182,249, 14/182,250, 14/182,251, 14/182,252, 14/182,256, 14/182,265, 14/182,268, 14/182,270, 14/182,277, 14/182,280, 14/183,245, 14/183,259, 14/183,274, 14/183,289, 14/183,309, 14/183,335, 14/183,371, 14/183,415, 14/183,422, 14/207,039, 14/260,120, 14/265,312, 14/548,191, 14/548,201, 14/677,872, 14/710,251, 14/744,850, 14/746,833, and 14/755,065.

Those of ordinary skill in the relevant fields of art will recognize that other inventive concepts may also be directly or inferentially disclosed in the foregoing. NO inventions are disclaimed.

1-4. (canceled)

5. A method for optimizing a power semiconductor device which includes: a first-type semiconductor die having first and second surfaces; first and second second-type emitter/collector regions, located respectively on the first and second; first and second first-type base contact regions, located respectively on the first and second surfaces; and first and second trenched field plate structures, which are located respectively on the first and second surfaces and abutting the first and the second emitter/collector regions respectively, and which each include a respective conductor separated from the die by a respective dielectric; comprising the actions of:
adjusting the thickness of the dielectric in the trenched field plate structures to be large enough to withstand the base-to-emitter voltage, but small enough to provide good electrical coupling between the poly field plate and the adjacent semiconductor die;
adjusting the minimum width of both of the base contact regions to be not only small enough to provide an acceptably low reverse base contact region pinch-off voltage, but also large enough to avoid degradation of base resistance;
and adjusting the minimum width of both of the emitter/collector regions to be small enough that current density is acceptably high at the center of thereof;
whereby, after fabrication of the resulting device, the breakdown voltage is improved under either polarity of applied voltage, degradation of base resistance is avoided, and emitter efficiency is kept acceptably high.

6. The method of claim 5, wherein the first type is p-type, and the second type is n-type.

7. The method of claim 5, wherein the semiconductor die is silicon, and the dielectric is an oxide.

8. The method of claim 5, wherein the minimum width of the base contact regions is determined by the lateral separation of portions of the trenched field plate structures.

9. The method of claim 5, wherein the minimum width of the emitter/collector regions is determined by the lateral separation of portions of the trenched field plate structures.

10. A power semiconductor device, comprising:
a p-type semiconductor die having first and second surfaces;
first and second n-type emitter/collector regions, located respectively on the first and second surface of the semiconductor die;
first and second p-type base contact regions, located respectively on the first and second surface of the semiconductor die;
first and second trenched field plate structures, located respectively on the first and second surface of the semiconductor die;
wherein the first emitter/collector region is electrically connected to, and is entirely surrounded by, the first trenched field plate structure;
wherein the second emitter/collector region is electrically connected to, and is entirely surrounded by, the second trenched field plate structure;
wherein the dielectric thickness in the trenched field plate structures is large enough to withstand the base-to-emitter voltage, but small enough to provide good electrical coupling between the poly field plate and the adjacent p-type silicon;
wherein the minimum width of both of the base contact regions is small enough to provide an acceptably low reverse base contact region pinch-off voltage, but large enough to avoid degradation of base resistance;
and wherein the minimum width of both of the emitter/collector regions is small enough that current density is acceptably high at the center of thereof;
whereby the breakdown voltage is improved under either polarity of applied voltage, degradation of base resistance is avoided, and emitter efficiency is kept acceptably high.

11. The device of claim 10, further comprising: first and second field-limiting ring structures, located respectively on the first and second surfaces of the die; wherein the first field-limiting ring structure surrounds the first emitter/collector region, the first trenched field plate structure, and the first base contact region; and wherein the second field-limiting ring structure surrounds the second emitter/collector region, the second trenched field plate structure, and the second base contact region.

12. The device of claim 10, wherein the semiconductor die is made of silicon.

13. The device of claim 10, wherein the trenched field plate structures comprise doped polysilicon field plates in oxide-lined trenches.

14. A power semiconductor device, comprising:
an n-type semiconductor die having first and second surfaces;
first and second p-type emitter/collector regions, located respectively on the first and second surface of the semiconductor die;
first and second n-type base contact regions, located respectively on the first and second surface of the semiconductor die;
first and second trenched field plate structures, located respectively on the first and second surface of the semiconductor die;
wherein the first emitter/collector region is electrically connected to, and is entirely surrounded by, the first trenched field plate structure;
wherein the second emitter/collector region is electrically connected to, and is entirely surrounded by, the second trenched field plate structure;
wherein the dielectric thickness in the trenched field plate structures is large enough to withstand the base-to-emitter voltage, but small enough to provide good electrical coupling between the poly field plate and the adjacent p-type silicon;
wherein the minimum width of both of the base contact regions is small enough to provide an acceptably low reverse base contact region pinch-off voltage, but large enough to avoid degradation of base resistance;
and wherein the minimum width of both of the emitter/collector regions is small enough that current density is acceptably high at the center of thereof;
whereby the breakdown voltage is improved under either polarity of applied voltage, degradation of base resistance is avoided, and emitter efficiency is kept acceptably high.

15. The device of claim 14, further comprising:
first and second field-limiting ring structures, located respectively on the first and second surfaces of the die;
wherein the first field-limiting ring structure surrounds the first emitter/collector region, the first trenched field plate structure, and the first base contact region; and
wherein the second field-limiting ring structure surrounds the second emitter/collector region, the second trenched field plate structure, and the second base contact region.

16. The device of claim 14, wherein the semiconductor die is made of silicon.

17. The device of claim 14, wherein the trenched field plate structures comprise doped poly field plates in oxide-lined trenches.
